(19) United States
(12) Patent Application Publication
(10) Pub. No.: US 2006/0176996 A1
(43) Pub. Date: Aug. 10, 2006

(54) Network-based TTL counter

(75) Inventors: Guy A. Urbina, Dublin, CA (US); Mark F. Cunningham, Oakland, CA (US)

Correspondence Address: James S. Tak;Assistant Laboratory Counsel, Lawrence Livermore National Laboratory, P.O. Box 808, L-703, Livermore, CA, 94551, US

(73) Assignee: The Regents of the University of California

(21) Appl. No.: 11/350,717

(22) Filed: Feb. 8, 2006

Related U.S. Application Data
(60) Provisional application No. 60/655,708, filed on Feb. 22, 2005.
(60) Provisional application No. 60/651,450, filed on Feb. 8, 2005.

(51) Int. Cl. H03K 23/66

(52) U.S. Cl. 377/52

(57) ABSTRACT

A network-based TTL counter having integrated components for processing TTL counts from sensor input and hosting the count data over a network. The TTL counter includes one or more TTL counters, each capable of receiving sensor input and outputting TTL pulse count data; a network node server for communication with a network as a node of the network and transmitting the count data to the network; one or more micro-controllers for controlling the TTL counter(s) and the network transmission of the count data; and a power source. As such TTL counts performed by the TTL counter may be remotely monitored anywhere over a network.

### I. CLAIM OF PRIORITY IN PROVISIONAL APPLICATION

This application claims the benefit of U.S. provisional application No. 60/651,450 filed Feb. 8, 2005, entitled, “Ethernet TTL Counter” and U.S. provisional application No. 60/655,708 filed Feb. 22, 2005, entitled, “Ethernet TTL Counter,” both by Guy A. Urbina et al.

The United States Government has rights in this invention pursuant to Contract No. W-7405-ENG-48 between the United States Department of Energy and the University of California for the operation of Lawrence Livermore National Laboratory.

### II. FIELD OF THE INVENTION

The present invention is directed to TTL counters, and more particularly to a network-based TTL counter apparatus for processing TTL counts and hosting count data over a Network connection as an autonomous device.

### III. BACKGROUND OF THE INVENTION

Counters are electronic devices which store the number of times a particular event or process has occurred, often in relation to a clock signal. And TTL counters in particular are counters which employ transistor-transistor logic (TTL), a common semiconductor technology using bipolar junction transistors and resistors for building discrete logic integrated circuits. TTL counters have typically been available as part of a PCI card, a common type of expansion card for attaching a peripheral device to a motherboard of a personal computer (PC). Counter control in such PCI cards is provided by the main CPU of the PC via the PCI bus, and counter output is also transmitted through the PCI bus. Only the sensor inputs connect directly to the PCI card and the counters.

Because such PCI card-based TTL counters depend on the main CPU of the PC to provide counter control, processing time is taken away from the CPU which can delay performance of other core processing tasks. Also, because PCI card-based TTL counters are operable only in conjunction with the PCs in which they are installed, this can be problematic for applications with minimum space and weight limitations.

### IV. SUMMARY OF THE INVENTION

One aspect of the present invention includes a network-based TTL event counter apparatus comprising: at least one TTL counter(s), each capable of receiving sensor input and outputting TTL pulse count data; communication port means for connecting to a network as a node thereof and transmitting the count data to the network; processor means for controlling the TTL counter(s) and the network transmission of the count data through the communication port means; and means for supplying power to the apparatus.

Another aspect of the present invention includes a network-based TTL event counter apparatus comprising: at least one TTL counter(s), each capable of receiving sensor input and outputting TTL pulse count data; a network device server for connecting to a network as a node thereof and transmitting the count data to the network; a FIFO buffer; a first micro-controller for controlling the TTL counter(s) and FIFO buffer input, and administrating the data bus for the TTL counter(s) and the FIFO buffer; a second micro-controller for controlling FIFO buffer output and forwarding the count data from the FIFO buffer to the network device server; an oscillator for providing timing to the first and second processors; and means for supplying power to the apparatus.

Another aspect of the present invention includes a network-based TTL event counter apparatus comprising: a field programmable gate array (FPGA) having code means programmed thereon for counting TTL events and transmitting count output over a network, said code means comprising: TTL counter means for causing the FPGA to receive at least one sensor input, count TTL pulses from each sensor input, and output TTL count data associated with each sensor input; communication port means for causing the FPGA to connect to a network as a node thereof and transmit the count data to the network; and processor means for causing the FPGA to control the TTL counter means and the communication port means.

### V. BRIEF DESCRIPTION OF THE DRAWINGS

The accompanying drawings, which are incorporated into and form a part of the disclosure, are as follows:

FIG. 1 is a schematic block diagram of a first preferred embodiment of the network-based TTL counter of the present invention illustrating the top-level modules and general operation of the TTL counter.

FIG. 2 is a schematic block diagram of a second preferred embodiment of the network-based TTL counter of the present invention showing the control and data flow between particular modules of the TTL counter.

### VI. DETAILED DESCRIPTION

Generally, the present invention is a miniature electronic counter device for counting TTL pulses and transmitting the counted output through a data network, such as Ethernet. In particular, the present invention is a self-contained, stand-alone TTL counter apparatus which incorporates TTL counter electronics, processing electronics, and network connectability (as a node on a network) in a compact integrated platform for use in remote sensing/monitoring applications, such as neutron monitoring.

The compact integrated platform is preferably embodied as a compact unit assembly of commercial off-the-shelf (COTS) components (e.g. COTS integrated circuits), or in the alternative implemented as a field programmable gate array (FPGA), or a pre-programmed integrated circuit (IC). In any case, because an onboard processor(s) is incorporated into the TTL counter apparatus for internal processing of count data, a separate computer or signal processor (e.g. CPU of a PC) is not required to provide the computing/processing power and is therefore capable of autonomous operation. It is notable for the FPGA embodiment that the methods and functionalities of the present invention are defined in software which is programmed onto an FPGA, and no other system components are needed. Such FPGA implementation (i.e. software defined TTL counter) may be preferred due to the greater number of channels and higher count rates possible. For example, in the FPGA embodiment, the network-based TTL counter apparatus of the present invention can count in the ranges of 1 Hz to hundreds of MHz.

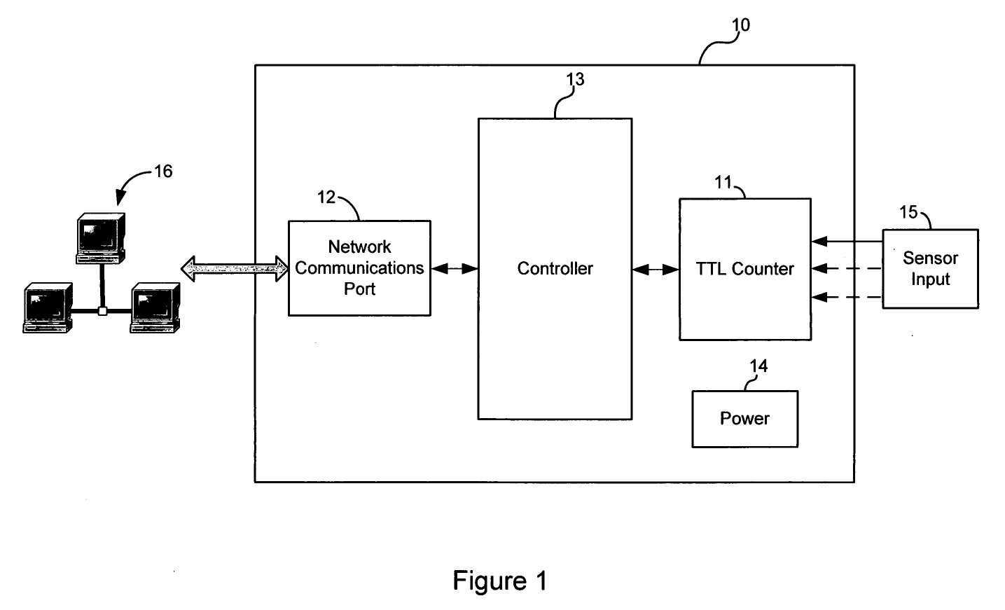

Turning now to the drawings, FIG. 1 shows a schematic block diagram of a first preferred embodiment of the network-based TTL counter of the present invention, indicated at reference character 10, and illustrating the main operational modules contained therein. First, a TTL counter module 11 is shown representing one or more TTL counters capable of receiving sensor input 15 from an offboard sensor/detector, and counting TTL pulses therefrom. Preferably, a plurality of counters are used, each associated with an input channel of a multi-channel sensor/detector. And each counter is capable of high resolution; in an exemplary embodiment of the present invention, six 16-bit counters are used, with each counter capable of counting TTL pulses 20 ns wide, over a configurable gate time. The TTL counter's count resolution can be any range suitable for a given application, but preferably extends down to about a 20 ns rate. For FPGA embodiments of the present invention, count resolutions can approach single nanosecond rates.

A network communications port module 12 is also shown in FIG. 1 capable of communicating with a network 16 for transmitting counted data. The network communications port module represents all the components, electronic and otherwise, which enable the connection of the apparatus 10 to the network as a node of the network. In particular, the network communications port module preferably includes a self-contained, configurable network node server having its own TCP/IP protocol stack, for hosting all the TTL counts sent out via TCP/IP. This physical layer allows TTL counting to be remotely monitored anywhere over a network. It is notable that while the network node server is preferably an Ethernet device server providing Ethernet connection, it is not limited only to such. In the alternative, the TTL counter apparatus of the present invention may use any other method for establishing a network node with TCP/IP stack, such as for example the 802.11B/G wireless standard (for bridging to Ethernet networks and/or Mesh networks), wireless, Bluetooth, or any other physical layer known in the art.

A controller module 13 is also generally shown for controlling other components of the unit, such as the components of the TTL counter module 11, and the data flow to the network communications port module 12 for network data transmission. The controller module may include, for example, one or more microcontrollers/processors, and memory such as a FIFO buffer for data storage. Other electronics components necessary for proper operation of the micro-controllers may also be considered part of the controller module, such as an oscillator IC which provides the timing necessary for the microcontrollers. It is notable that the function of the network node server, such as an Ethernet port device server, may be integrated into and provided by a micro-controller. As such the particular network connection modality of the network node server described above is not limited to a discrete component, but rather includes all modalities for hosting data on a network.

Finally, FIG. 1 shows a power module 14 representing all components necessary for supplying power to operate the apparatus 10. Power may be supplied by an onboard power source, such as a battery (not shown), for portable operation, or be connected to an off board power source (not shown) as known in the art. As such, the power module 14 may include, for example, an onboard power source (e.g. a battery), or power cables or other means for connecting to an offboard power source, as well as a power regulator (not shown) and other electronics necessary for delivering usable power to the apparatus. It is notable in an Ethernet implementation, that the off-board power source can be POE (Power Over Ethernet) which is an IEEE industry standard off-board power source.

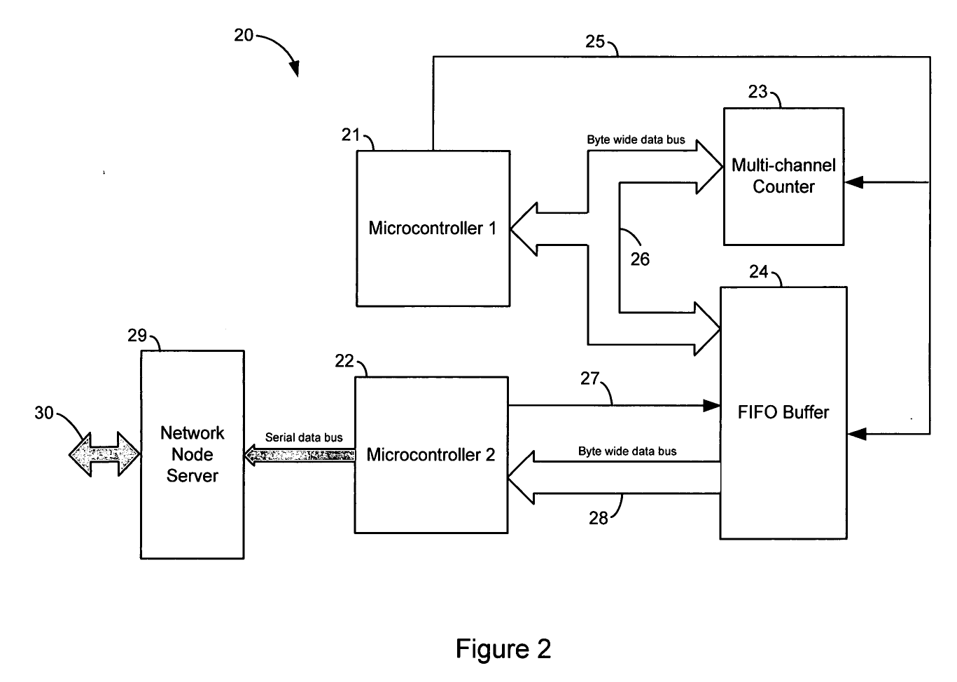

FIG. 2 shows a control block diagram of a second preferred embodiment 20 of the network-based TTL counter apparatus of the present invention showing the internal processing of TTL counts and conversion of the counts to an ASCII data stream sent out via TCP/IP over a configurable, self-contained network physical layer. The apparatus 20 is shown having a first micro-controller IC 21, a second micro-controller IC 22, a multi-channel counter/timer IC 23, a FIFO buffer 24, and a network node server 29. Generally, the first micro-controller 21 provides the control lines 25 for the counter IC 23, as well as the FIFO buffer 24. And as shown by arrows 26, the first micro-controller also administrates the 8-bit (byte) wide data bus for each counter of the multi-channel counter 23 and the FIFO buffer 24. The FIFO buffer 24 is preferably a dual port memory that loads and empties data on a first in, first out basis. And the second micro-controller 21 operates to fetch raw count data from the FIFO buffer, convert it into ASCII, and push the data out via serial stream to the network node server 29 which transmits it to a network as indicated by arrow 30. As suggested in FIG. 1, the first and second micro-controllers 21, 22 and the FIFO buffer 24 may be combined in a single processor performing all functions of the individual components.

An example prototype of the apparatus 20 was assembled by Applicants from COTS ICs having specific component specifications discussed herein for illustrative purposes only. In particular, the example prototype was assembled as an Ethernet TTL counter having six 16-bit TTL counters with 20 ns resolution counting up to 65535 over a configurable gate time. Eight separate COTS ICs and a COTS Ethernet device server were used in the assembly including the following:

(1) A 20 MHz TTL oscillator (commercially available from CTS, Inc.) for providing timing for the micro-controllers. This allows the micro-controllers to achieve 5 MIPS. (5 million instructions per second).

(2) A PIC16C63 type 8-bit CMOS micro-controller (hereinafter “PIC16C63” and commercially available from Microchip, Inc.) having 4K×14 words program memory, 192×8 bit RAM, and 22 I/O pins.

(3) and (4) Two CTS82C54 type 50 Mhz 3-channel counter/timer integrated circuits (hereinafter “CTS82C54” and commercially available from CTS, Inc.), which provides for a total of 6 high performance 16-bit programmable timers. These ICs are put into a specific mode of operation by the PIC16C63 micro-controller to output count values to the 8-bit data bus while still counting.

(5) A PIC16C711 type 8-bit CMOS micro-controller (hereinafter “PIC16C711” and commercially available from Microchip, Inc.) having 2K×14 words program memory, 128×8 bit RAM, and 13 I/O pins.

(6) An IDT 7200 256×9 Asynchronous FIFO buffer (hereinafter “IDT 7200” and commercially available from IDT, Inc.) which is a dual port memory that loads and empties data on a first in, first out basis. The PIC16C63 micro-controller loads count data via the 8-bit data bus, and the PIC16C711 micro-controller fetches count data.

(7) A 78SR105HC type 1.5A 5V Positive Step Down Integrated Switching Regulator (hereinafter “78SR105HC” and commercially available from Texas Instruments, Inc.) to provide a 5-volt bus voltage and has a wide input range of 7 to 30V. This allows the Ethernet TTL counter to be powered under 12V operation.

(8) A LM1086 3.3V Low Dropout Positive Regulator (hereinafter “LM1086” and commercially available from National Semiconductor, Inc.) to provide a 3.3-volt bus voltage for the Ethernet device server.

And (9) A Lantronix X-Port Device Server (commercially available from Lantronix, Inc.) to connect the PIC16C711 micro-controller to the Ethernet network. The device has its own full TCP/IP protocol stack.

The theory of operation for the second preferred embodiment is next discussed with reference to the example prototype assembled by the Applicants as follows. First, when power is applied, (nominally 12 volts) the 5-volt power bus via 78SR105HC is applied to all of the integrated circuits. 10K resistors on pin 4 of PIC16C711 and pin 1 of PIC16C63 allow proper Power On Resets of the micro-controllers. LM1086 converts the 5 volts to 3.3 volts for powering the Lantronix X-Port Device Server.

The 20 Mhz TTL Oscillator begins to run allowing micro-controllers (PIC16C63, PIC16C711) to wake up and begin running their code. PIC16C711 begins by waiting for the Ethernet device server to boot before proceeding, whilst PIC16C63 begins to reset the FIFO buffer.

After PIC16C63 resets the IDT 7200 FIFO buffer, it begins to initialize and setup both counters (CTS82C54). PIC16C63 sets the 8-bit data bus to output mode to send out commands. All counters are setup in event counter mode, loaded with a terminal count (65535) and preset for Hexadecimal output.

All counts are input through six female SMA connectors at the front of the PCB. These in turn have 10K pull down resistors to keep the clock lines at a low logic level. The clock lines are connected to Pins 9, 15, and 18 of counters CTS82C54 and CTS82C54.

After the counters have been set to an initial state, PIC16C63 asserts the Gate pins on the counters (pins 11, 14 and 16 of counters CTS82C54 and CTS82C54). This arms all counters to begin counting. PIC16C63 ticks off a time interval of 250 msec, which allows all counters to count down for that period of time. PIC16C63 then sends a read back command to latch all the counts. This occurs without inhibiting the counts.

PIC16C63 now sets the 8-bit data bus to read mode before reading back the counts from the latches. PIC16C63 sequentially fetches a 16-bit count from each of the 6 counters with two 8-bit reads on the data bus for a total of 12 reads. Additionally, PIC16C63 enables the Write pin of the IDT 7200 FIFO buffer and these 6 counts are pushed into the FIFO buffer. PIC16C63 also monitors the FIFO Full flag on pin 8 of IDT 7200 in case of overflow. If the IDT 7200 FIFO buffer is full, PIC16C63 will wait for the full flag to assert low before continuing.

After successfully pushing the 6 counts to the FIFO buffer, PIC16C63 disables the Write pin of IDT 7200 and reads the status bytes of each counter to see if the counters have overflowed. If any one of the counters have overflowed, PIC16C63 will push a terminal count (65535) into the IDT 7200 FIFO buffer to signify that an overflow has occurred. This will continue until all overflows have been resolved. If all is well, PIC16C63 will set the 8-bit data bus back to output and begin another iteration, jumping back to asserting the Gate inputs of the counters high and letting them count for another iteration of 250 msec. This describes the operation of PIC16C63 and its control over CTS82C54, CTS82C54 and IDT 7200.

In the meantime, PIC16C711 has been waiting for a time delay to allow the Ethernet device server to boot. After this time period PIC16C711 monitors the Empty Flag pin on the IDT 7200 FIFO buffer. If empty, PIC16C711 will continue to wait. If not empty, PIC16C711 will enable the Read pin on IDT 7200 FIFO buffer and begin to fetch count bytes from IDT 7200 over the bus. This will take 12 bytes to make up 6 counts.

After PIC16C711 fetches the counts, it begins a process of converting the raw hex count to ASCII values. It starts with converting all the counts to ones' complement. This is necessary because the counters (CTS82C54, CTS82C54) count downwards only. PIC16C711 then makes a copy of these counts in temporary variables for later use. In order to get an event count at any given point in time, PIC16C711 subtracts the original counts from previous counts unless this is the first iteration whereby it will subtract zero from the original count.

PIC16C711 then converts and unpacks these difference count values into BCD bytes and finally, the BCD counts are converted into 5 digit ASCII characters. ASCII characters A-F are used to signify and separate the six counts individually. PIC16C711 then transmits these ASCII characters out serially at a baud rate of 57600 to the Lantronix X-Port device server. This occurs every 250 msec for a refresh rate of 4 Hz.

Afterwards, PIC16C711 moves the temporary count variables into a different set of variables for use by successive iterations. PIC16C711 has completed an iteration of the program loop and jumps back to monitoring the Empty status of the FIFO buffer to fetch another 6 count words.

After its boot sequence is finished, the Lantronix X-Port Device Server wakes up and listens for a TCP connection. As soon as it is connected via TCP/IP, it awaits the count data on its serial transmit pin (5) from PIC16C711 Pin 17 and transmits the count data over Ethernet to the client host. The Lantronix X-Port's serial port is configured for 57600 baud to match the connection for PIC16C711.

The network-based TTL counter of the present invention is preferably used to count TTL pulses from He-3 detectors in a neutron counting application, i.e. as a network-based neutron counter as part of a network based radiation area monitor. It is notable that the TTL counter of the present invention does not implement a neutron detector or any detector. Instead, it simply counts TTL pulses from the outputs of any COTS neutron detector.

Additionally, it is appreciated that the network-based TTL counter is not exclusive to neutron counting, but can count any TTL pulse from any source or device within its specifications, such as for example but not limited to:

(1) In addition to He-3 detectors, the network-based TTL event counter can be interfaced with plastic scintillator detectors for gamma ray detection.

(2) The TTL counter of the present invention can also interface to a Doppler Radar Sensor with TTL output for remote sensing of speed.

(3) Remote sensing of TOF (time of flight) distance measurement. The event counter can interface to laser or radar sensor with TTL output.

(4) The TTL counter can be used for remote sensing of presence and detection via photo gates interface.

(5) The TTL counter can be used for remote real time traffic counting.

(6) The event counter can be used for remote monitoring/counting of contact closures i.e. (doors, windows, panels opening and closing)

(7) And other uses may include for example a network based industrial counter.

While particular operational sequences, materials, temperatures, parameters, and particular embodiments have been described and or illustrated, such are not intended to be limiting. Modifications and changes may become apparent to those skilled in the art, and it is intended that the invention be limited only by the scope of the appended claims.

I claim:

1. A network-based TTL event counter apparatus comprising:
at least one TTL counter(s), each capable of receiving sensor input and outputting TTL pulse count data;
communication port means for connecting to a network as a node thereof and transmitting the count data to the network;
processor means for controlling the TTL counter(s) and the network transmission of the count data through the communication port means; and
means for supplying power to the apparatus.

2. The TTL counter apparatus of claim 1,
wherein the processor means includes a FIFO buffer, a first micro-controller capable of controlling the TTL counter(s) and FIFO buffer input and administrating data buses for the TTL counter(s) and the FIFO buffer, a second micro-controller capable of controlling FIFO buffer output and forwarding the count data from the FIFO buffer to the communication port means for network transmission; and an oscillator for providing timing to the first and second micro-controllers.

3. The network-based TTL event counter apparatus of claim 1,
further comprising two 16-bit TTL counters.

4. The network-based TTL event counter apparatus of claim 3,
wherein each of the TTL event counter(s) is capable of resolving down to 20 ns pulse widths.

5. The network-based TTL event counter apparatus of claim 1,
wherein the communication port means is a network node server having a TCP/IP protocol stack.

6. The network-based TTL counter apparatus of claim 1,
wherein the means for supplying power to the apparatus comprises means for connecting to an off-board power source.

7. The network-based TTL counter apparatus of claim 6,
wherein the off-board power source is POE (Power Over Ethernet), an IEEE industry standard off-board power source.

8. The network-based TTL counter apparatus of claim 1,
wherein the means for supplying power to the apparatus comprises an on-board power source.

9. A network-based TTL event counter apparatus comprising:
at least one TTL counter(s), each capable of receiving sensor input and outputting TTL pulse count data;
a network device server for connecting to a network as a node thereof and transmitting the count data to the network;
a FIFO buffer;
a first micro-controller for controlling the TTL counter(s) and FIFO buffer input, and administrating the data bus for the TTL counter(s) and the FIFO buffer;
a second micro-controller for controlling FIFO buffer output and forwarding the count data from the FIFO buffer to the network device server;
an oscillator for providing timing to the first and second processors; and
means for supplying power to the apparatus.

10. The network-based TTL event counter apparatus of claim 9,
further comprising two 16-bit TTL counters.

11. The network-based TTL event counter apparatus of claim 10,
wherein each of the TTL event counter(s) is capable of resolving down to 20 ns pulse widths.

12. The network-based TTL event counter apparatus of claim 9,
wherein the network device server has a TCP/IP protocol stack.

13. The network-based TTL counter apparatus of claim 1,
wherein the means for supplying power to the apparatus comprises means for connecting to an off-board power source.

14. The network-based TTL counter apparatus of claim 13,
wherein the off-board power source is POE (Power Over Ethernet), an IEEE industry standard off-board power source.

15. The network-based TTL counter apparatus of claim 9,
wherein the means for supplying power to the apparatus comprises an on-board power source.

16. A network-based TTL event counter apparatus comprising:
a field programmable gate array (FPGA) having code means programmed thereon for counting TTL events and transmitting count output over a network, said code means comprising:
TTL counter means for causing the FPGA to receive at least one sensor input, count TTL pulses from each sensor input, and output TTL count data associated with each sensor input;
communication port means for causing the FPGA to connect to a network as a node thereof and transmit the count data to the network; and
processor means for causing the FPGA to control the TTL counter means and the communication port means.
